(19) United States
(12) Patent Application Publication
(10) Pub. No.: US 2025/0287724 A1
(43) Pub. Date: Sep. 11, 2025

(54) OPTICAL DEVICE

(71) Applicant: TONG HSING ELECTRONIC INDUSTRIES, LTD., Taoyuan City (TW)

(72) Inventors: Kuan-Hsun Wu, Taoyuan City (TW); CHIA-MIN WU, Taoyuan City (TW); TAI-YEN CHEN, Taoyuan City (TW); YU-CHIAO TSENG, Taoyuan City (TW); CHING-TENG HUANG, Taoyuan City (TW); CHI-LUNG HO, Taoyuan City (TW); WEN-FU YU, Taoyuan City (TW); WEI-LI WANG, Taoyuan City (TW); JYUN-HUEI JIANG, Taoyuan City (TW)

(21) Appl. No.: 18/895,406

(22) Filed: Sep. 25, 2024

Related U.S. Application Data
(60) Provisional application No. 63/561,356, filed on Mar. 5, 2024.

(30) Foreign Application Priority Data
Jun. 11, 2024 (TW) 113121408

(51) Int. Cl. H01L 31/0203; H01L 23/26; H01L 23/31; H01L 31/02

(52) U.S. Cl. CPC H10F 77/50; H01L 23/26; H01L 23/3128; H10F 77/93

(57) ABSTRACT

An optical device includes an electronic component, a light-permeable layer, and a ring-shaped support that is sandwiched between the electronic component and the light-permeable layer. A top surface of the electronic component includes an optical region and a carrying region that surrounds the optical region. The ring-shaped support includes an adhesive layer and an additive module that is incompletely soluble in the adhesive layer. The adhesive layer is ring-shaped and is disposed on the carrying region of the electronic component. The additive module includes a plurality of inner additives and a plurality of shape-formation additives, which are entirely embedded in the adhesive layer. The inner additives are arranged away from inner side and outer side of the adhesive layer. The shape-formation additives are arranged adjacent to the inner side, so as to enable the inner side to form a plurality of protruding microstructures.

### CROSS-REFERENCE TO RELATED PATENT APPLICATION

This application claims the benefit of priority to Taiwan Patent Application No. 113121408, filed on Jun. 11, 2024. The entire content of the above identified application is incorporated herein by reference.

This application claims the benefit of priority to the U.S. Provisional Patent Application Ser. No. 63/561,356, filed on Mar. 5, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optical device, and more particularly to an optical device having a ring-shaped support that can weaken light.

### BACKGROUND OF THE DISCLOSURE

A conventional optical device includes a glass sheet, an optical component, and an adhesive layer that is adhered to and sandwiched between the glass sheet and the optical component. However, in the conventional optical device, light traveling on to the adhesive layer can easily have an abnormal refraction or an abnormal reflection.

### SUMMARY OF THE DISCLOSURE

In response to the above-referenced technical inadequacies, the present disclosure provides an optical device for effectively improving on the issues associated with conventional optical devices.

In order to solve the above-mentioned problems, one of the technical aspects adopted by the present disclosure is to provide an optical device, which includes an electronic component, a ring-shaped support, and a light-permeable layer. A top surface of the electronic component has an optical region and a carrying region that surrounds the optical region. The ring-shaped support includes an adhesive layer and an additive module. The adhesive layer has a ring shape and is disposed on the carrying region of the electronic component.

The adhesive layer has an inner side and an outer side that is opposite to the inner side. The additive module is incompletely soluble in the adhesive layer and includes a plurality of inner additives and a plurality of shape-formation additives. The inner additives are entirely embedded in the adhesive layer and are arranged away from the inner side and the outer side of the adhesive layer. The shape-formation additives are entirely embedded in the adhesive layer. The shape-formation additives are arranged adjacent to the inner side of the adhesive layer, so as to enable the inner side of the adhesive layer to form a plurality of protruding microstructures. The light-permeable layer has an outer surface and an inner surface that is opposite to the outer surface. The light-permeable layer is disposed on the ring-shaped support, and the inner surface of the light-permeable layer, the ring-shaped support, and the electronic component jointly define an enclosed space.

Therefore, the adhesive layer of the optical device in the present disclosure is provided with the protruding microstructures through the additive module arranged therein, such that light traveling on to the inner side of the adhesive layer can be weakened through the protruding microstructures, thereby effectively preventing the light traveling on to the ring-shaped support from generating an abnormal refraction or reflection.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an optical device in a first configuration according to an embodiment of the present disclosure;

FIG. 2 is a schematic cross-sectional view taken along line II-II of FIG. 1;

FIG. 3A is an enlarged view of part IIIA of FIG. 2;

FIG. 3B is an enlarged view of part IIIB of FIG. 2;

FIG. 3C is a schematic cross-sectional view showing a formation process of a ring-shaped support shown in FIG. 3A;

FIG. 4A is a schematic top view of FIG. 1 with a light-permeable layer and an encapsulant being omitted;

FIG. 4B is an enlarged view of part IVB of FIG. 4A;

FIG. 5 is a partial schematic top view showing the optical device in a second configuration with the light-permeable layer and the encapsulant being omitted;

FIG. 6 is a partial schematic top view showing the optical device in a third configuration with the light-permeable layer and the encapsulant being omitted;

FIG. 7 is a partial schematic top view showing the optical device in another mode of the third configuration with the light-permeable layer and the encapsulant being omitted;

FIG. 8 is a partial schematic top view showing the optical device in a fourth configuration with the light-permeable layer and the encapsulant being omitted;

FIG. 9 is a partial schematic top view showing the optical device in a fifth configuration with the light-permeable layer and the encapsulant being omitted;

FIG. 10 is a partial schematic top view showing the optical device in a sixth configuration with the light-permeable layer and the encapsulant being omitted;

FIG. 11 is a partial schematic top view showing the optical device in a seventh configuration with the light-permeable layer and the encapsulant being omitted;

FIG. 12 is a schematic cross-sectional view showing the optical device being a sensor package structure with the encapsulant being omitted; and

FIG. 13 is a schematic cross-sectional view showing the optical device being a display mechanism.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

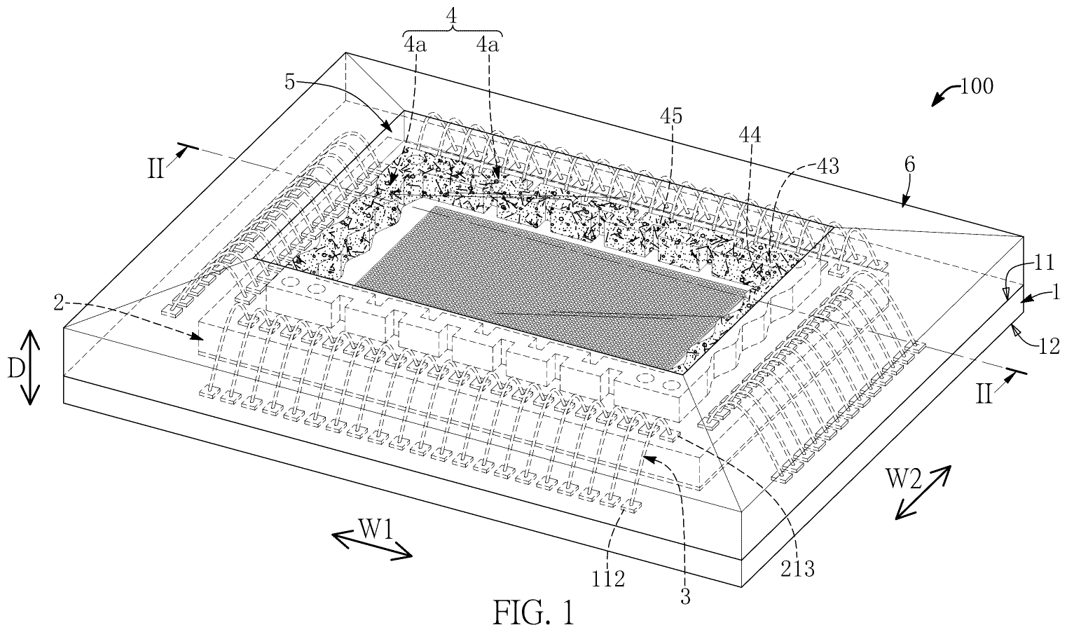

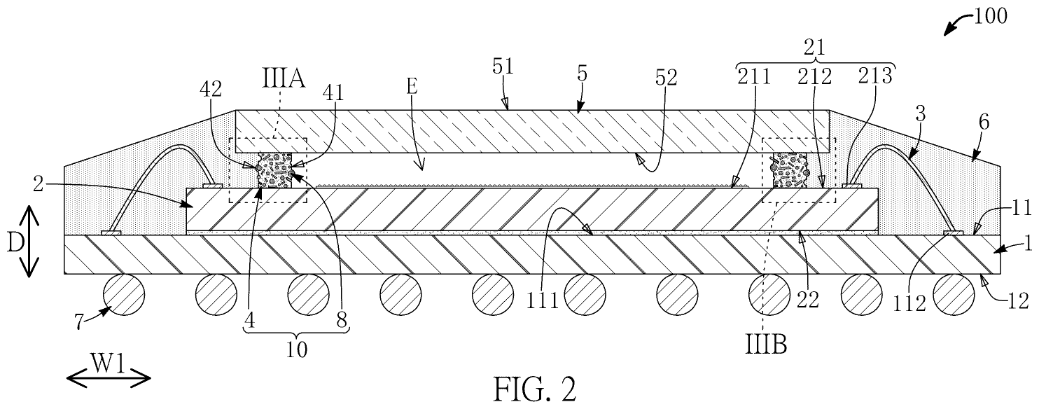

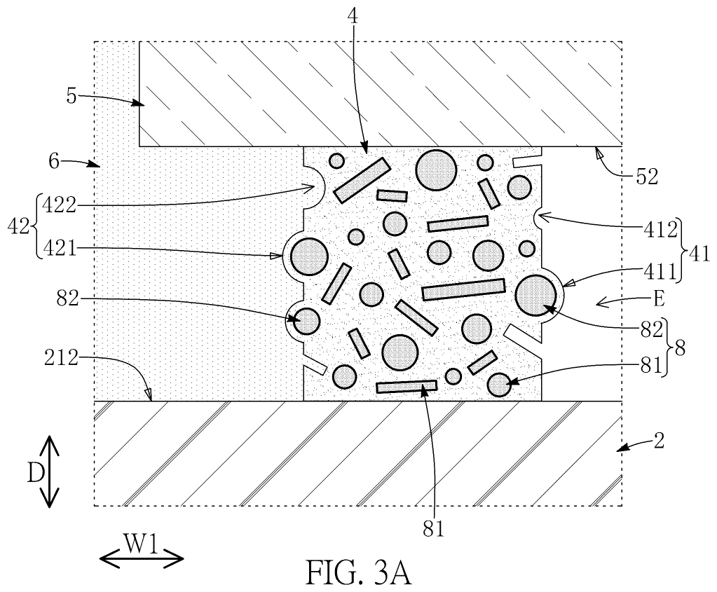

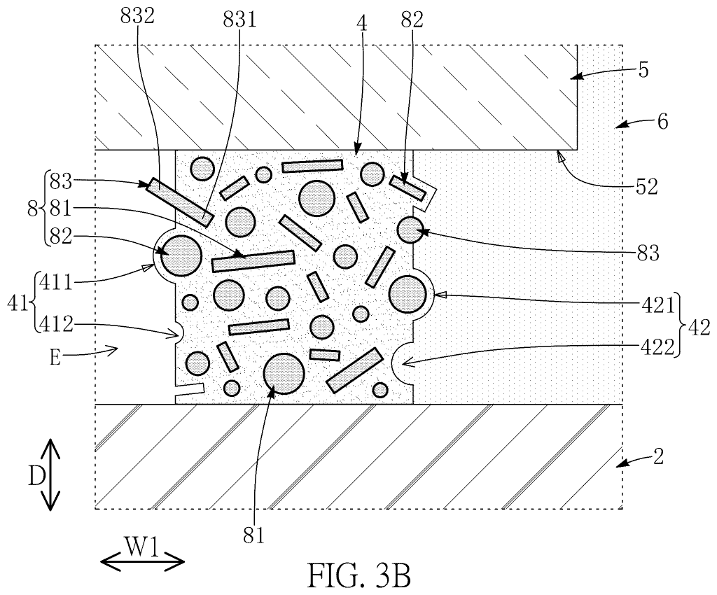

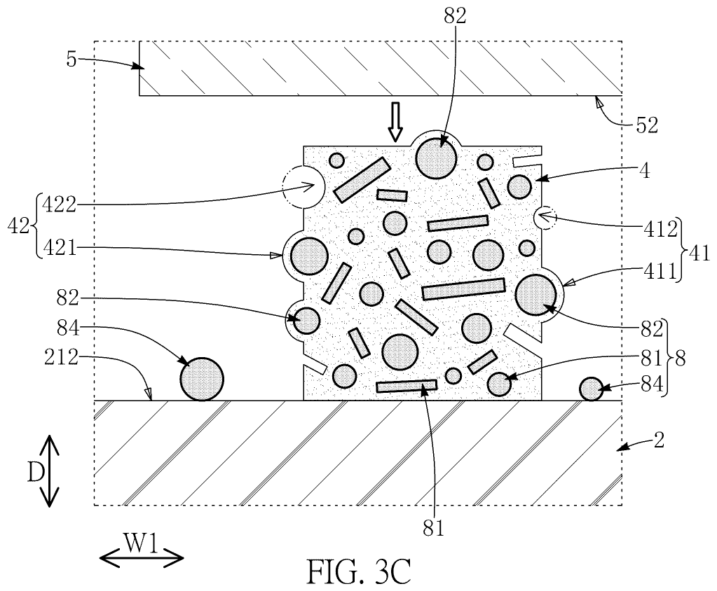

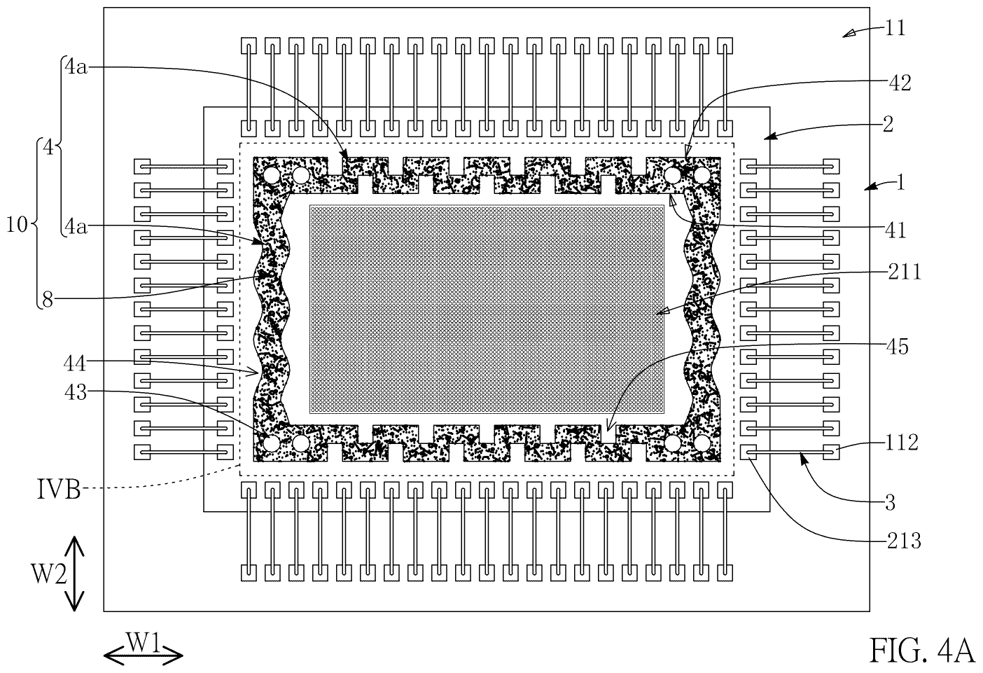

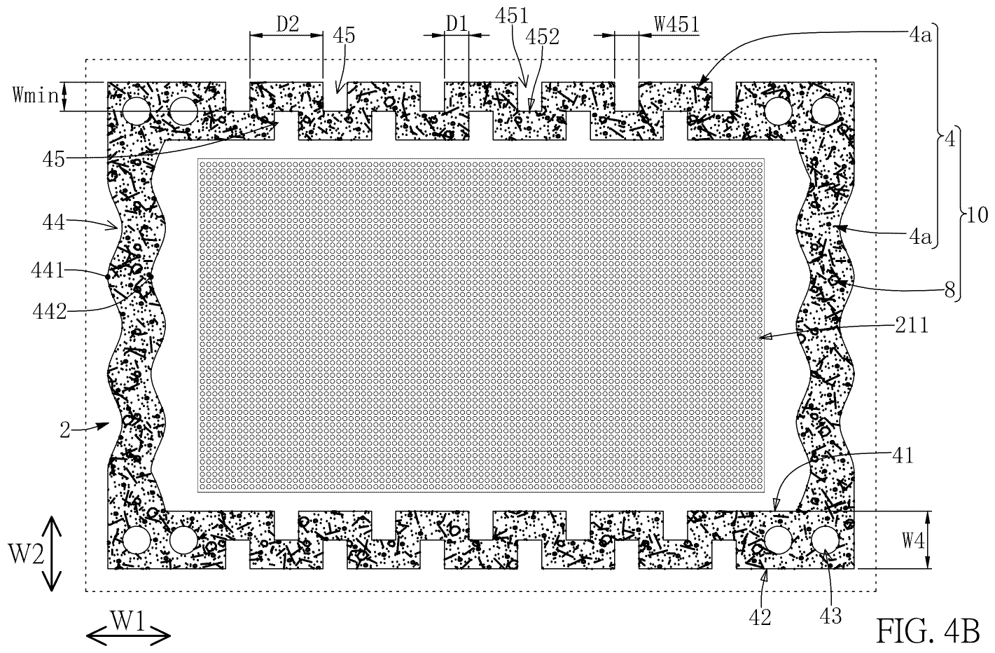

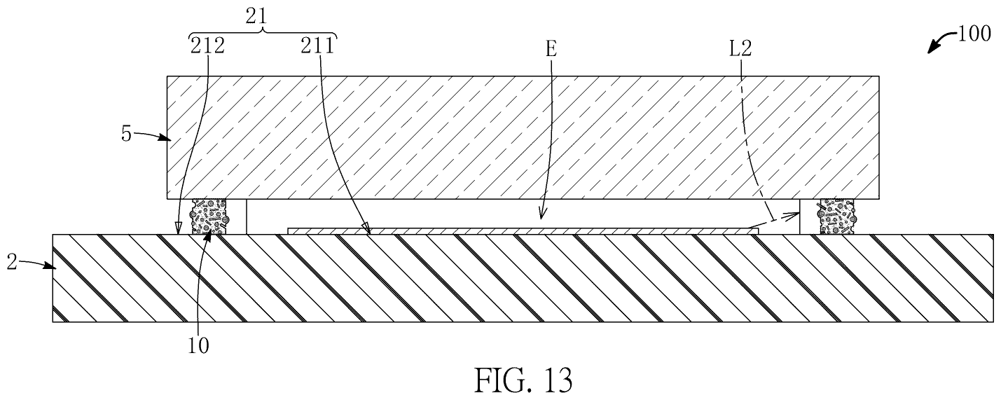

Referring to FIG. 1 to FIG. 13, an embodiment of the present disclosure provides an optical device 100. In the present embodiment, the optical device 100 can be a sensor package structure as shown in FIG. 1 to FIG. 12 and being described in the corresponding description, and the optical device 100 can be a display mechanism as shown in FIG. 13 and being described in the corresponding description.

As shown in FIG. 1 to FIG. 4B, the optical device 100 includes a substrate 1, an electronic component 2 disposed on the substrate 1, a plurality of metal wires 3 electrically coupled to the electronic component 2 and the substrate 1, a ring-shaped support 10 disposed on the electronic component 2, a light-permeable layer 5 disposed on the ring-shaped support 10, and an encapsulant 6 that is formed on the substrate 1. The ring-shaped support 10 is sandwiched between the electronic component 2 and the light-permeable layer 5 along a predetermined direction D, and the ring-shaped support 10 includes an adhesive layer 4 having a ring shape and being disposed on the electronic component 2 and an additive module 8 that is incompletely soluble in the adhesive layer 2.

The optical device 100 in the present embodiment includes the above components, but can be adjusted or changed according to design requirements.

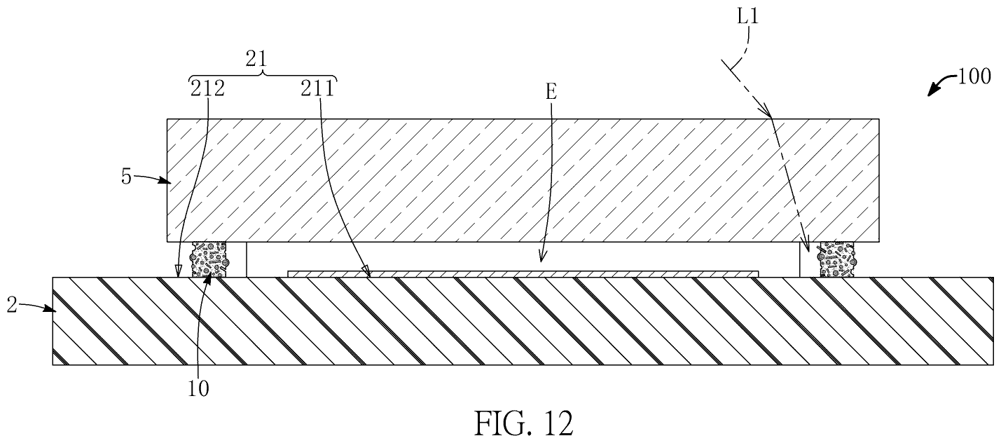

For example, as shown in FIG. 12, the optical device 100 can be provided without the substrate 1 and the encapsulant 6; or, in other embodiments of the present disclosure not shown in the drawings, the optical device 100 can be provided without the metal wires 3, and the electronic component 2 is fixed onto and electrically coupled to the substrate 1 in a flip-chip manner or an adhering manner. The structure and connection relationship of each component of the optical device 100 will be recited in the following description.

The substrate 1 of the present embodiment has a square shape or a rectangular shape, but the present disclosure is not limited thereto. An upper surface 11 of the substrate 1 includes a chip-bonding region 111 arranged approximately on a center portion thereof, and the substrate 1 includes a plurality of bonding pads 112 that are disposed on the upper surface 11 and are arranged outside of the chip-bonding region 111. The bonding pads 112 in the present embodiment are in a ring-shaped arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 can be further provided with a plurality of solder balls 7 disposed on a lower surface 12 thereof. The substrate 1 can be soldered onto an external electronic component (not shown in the drawings) through the solder balls 7, thereby electrically connecting the optical device 100 to the external electronic component.

The electronic component 2 in the present embodiment has a square shape or a rectangular shape and is an image electronic component, but the present disclosure is not limited thereto. A bottom surface 22 of the electronic component 2 is fixed onto the chip-bonding region 111 of the substrate 1 (through a chip-bonding adhesive) along the predetermined direction D. In other words, the electronic component 2 is arranged to be surrounded on the inside of the bonding pads 112. Moreover, a top surface 21 of the electronic component 2 has an optical region 211 and a carrying region 212 that has a ring shape arranged around the optical region 211. Two ends of each of the metal wires 3 are respectively connected to the substrate 1 and the carrying region 212 of the electronic component 2, so that the substrate 1 and the electronic component 2 are electrically coupled to each other.

Specifically, the electronic component 2 includes a plurality of connection pads 213 arranged on the carrying region 212. In other words, the connection pads 213 are arranged outside of the optical region 211. The number and positions of the connection pads 213 of the electronic component 2 in the present embodiment correspond to those of the bonding pads 112 of the substrate 1. In other words, the connection pads 213 in the present embodiment are substantially in a ring-shaped arrangement. Moreover, the two ends of each of the metal wires 3 are respectively connected to one of the bonding pads 112 and the corresponding connection pad 213.

The adhesive layer 4 in the present embodiment includes a plurality of segments 4a sequentially connected to form the ring shape (e.g., a rectangular ring shape) thereof. The adhesive layer 4 is disposed on the carrying region 212 of the electronic component 2 and surrounds the optical region 211, and each of the metal wires 3 is located outside of the adhesive layer 4. Moreover, the adhesive layer 4 has an inner side 41 and an outer side 42 that is opposite to the inner side 41. The inner side 41 is arranged adjacent to the optical region 211, and the outer side 42 is arranged away from the optical region 211.

In the present embodiment, the additive module 8 is completely insoluble in the adhesive layer 4 and includes a plurality of solid additives (e.g., carbon blacks) that are preferably made of a light-absorption material, and the adhesive layer 4 is light-permeable, such that when light travels in the adhesive layer 4, the additive module 8 absorbs at least part of the light, but the present disclosure is not limited thereto. For example, in other embodiments of the present disclosure not shown in the drawings, the additive module 8 can be made of a non-absorption material for light; or, the adhesive layer 4 can be translucent or opaque.

Specifically, the solid additives of the additive module 8 can be classified according to positions thereof with respect to the adhesive layer 4. The additive module 8 (i.e., the solid additives) can include a plurality of inner additives 81, a plurality of shape-formation additives 82, and a plurality of exposed additives 83. In the present embodiment, according to practical requirements, the inner additives 81, the shape-formation additives 82, and the exposed additives 83 have at least two shapes (e.g., a rod-like shape and a spherical shape) different from each other, but the present disclosure is not limited thereto. For example, in other embodiments of the present disclosure not shown in the drawings, the inner additives 81, the shape-formation additives 82, and the exposed additives 83 can have a same shape according to practical requirements.

Furthermore, the inner additives 81 are entirely embedded in the adhesive layer 4 and are arranged away from the inner side 41 and the outer side 42 of the adhesive layer 4. The shape-formation additives 82 are entirely embedded in the adhesive layer 4, and the shape-formation additives 82 are arranged adjacent to the inner side 41 and/or the outer side 42 of the adhesive layer 4, so as to enable the inner side 41 and/or the outer side 42 of the adhesive layer 4 to form a plurality of protruding microstructures 411, 421. In other words, a space surrounded by any one of the protruding microstructures 411, 421 is provided with at least part of a corresponding one of the shape-formation additives 82 arranged therein.

Moreover, each of the exposed additives 83 has an embedded portion 831 and an exposed portion 832. The embedded portion 831 of each of the exposed additives 83 is embedded in the adhesive layer 4, and the exposed portion 832 of each of the exposed additives 83 is exposed from the adhesive layer 4. In other words, any one of the exposed additives 83 protrudes from the adhesive layer 4 through the exposed portion 832 thereof.

In addition, when the ring-shaped support 10 of the optical device 100 is formed only on the electronic component 2, the additive module 8 further includes a plurality of dropped additives 84. The dropped additives 84 are peeled from the adhesive layer 4, so as to enable the inner side 41 and/or the outer side 42 of the adhesive layer 4 to form a plurality of dimpled microstructures 412, 422.

In summary, the adhesive layer 4 of the optical device 100 in the present embodiment can have the protruding microstructures 411, 421 and the dimpled microstructures 412, 422 through the additive module 8 arranged therein, such that light traveling on to the inner side 41 of the adhesive layer 4 can be weakened through the protruding microstructures 411, 421 and the dimpled microstructures 412, 422, thereby effectively preventing the light traveling on to the ring-shaped support 10 from generating an abnormal refraction or an abnormal reflection.

Moreover, in the optical device 100 of the present embodiment, the exposed portion 832 of any one of the exposed additives 83 of the ring-shaped support 10 protrudes from the inner side 41 of the adhesive layer 4 for weakening the light, thereby further preventing the light traveling on to the ring-shaped support 10 from generating the abnormal refraction or the abnormal reflection.

In other words, the inner side 41 and the outer side 42 are spaced apart from each other by a predetermined width W4 along a width direction W1, W2 perpendicular to the predetermined direction D. In the present embodiment, the width direction W1, W2 can be a direction perpendicular to any one of the segments 4a.

Specifically, since the adhesive layer 4 has a larger coefficient of thermal expansion (CTE) (e.g., the CTE of the adhesive layer 4 is at least three times the CTE of the light-permeable layer 5 or the CTE of the electronic component 2), the adhesive layer 4 in the optical device 100 of the present embodiment is selectively formed with at least one type of L number of buffering cavities 43, M number of wave-shaped slots 44, and N number of rectangular slots 45 (e.g., L is a positive integer, and any one of M and N is a positive integer greater than one) according to different requirements, thereby effectively reducing a stress strength generated from the adhesive layer 4.

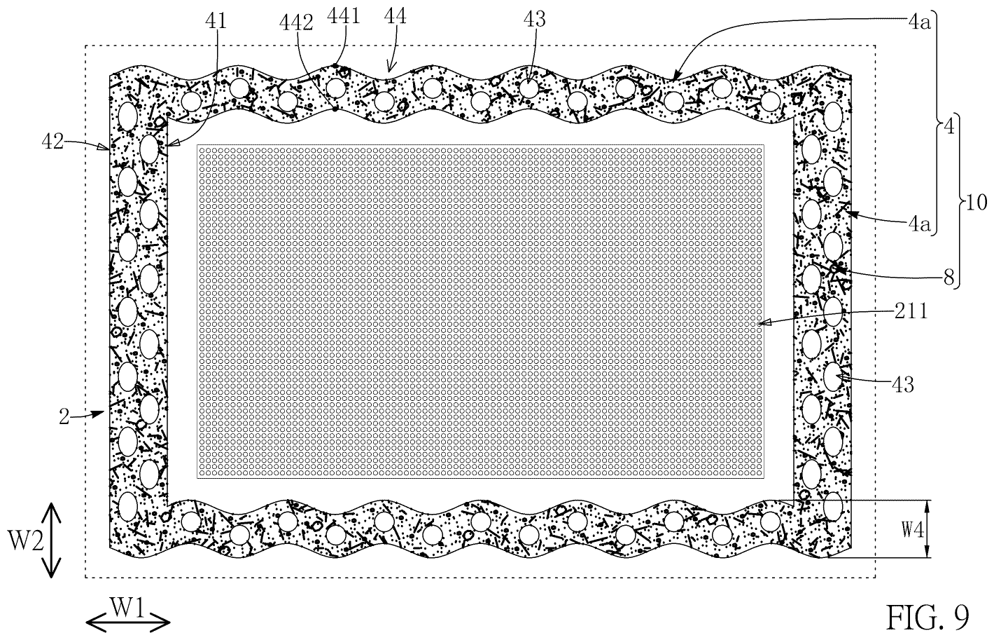

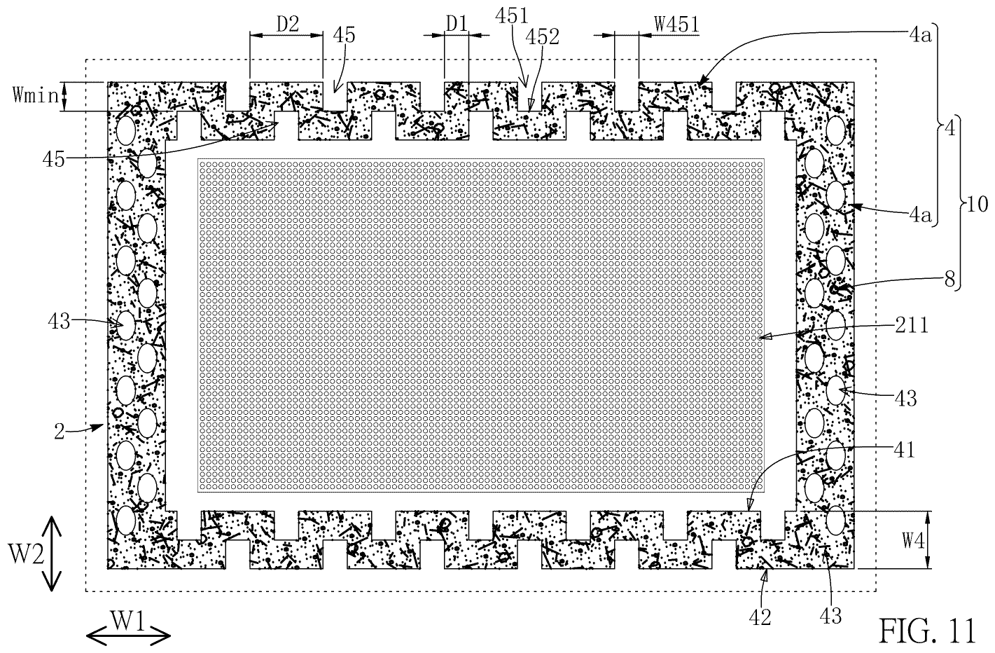

Specifically, when the adhesive layer 4 has the L number of the buffering cavities 43 (as shown in FIG. 1 to FIG. 7, FIG. 9, and FIG. 11), any one of the L number of the buffering cavities 43 is arranged in the adhesive layer 4 and penetrates through the adhesive layer 4 along the predetermined direction D. In other words, the L number of the buffering cavities 43 can be selectively provided and formed in the adhesive layer 4 in the above manner, and each of the buffering cavities 43 is provided without the additive module 8 therein.

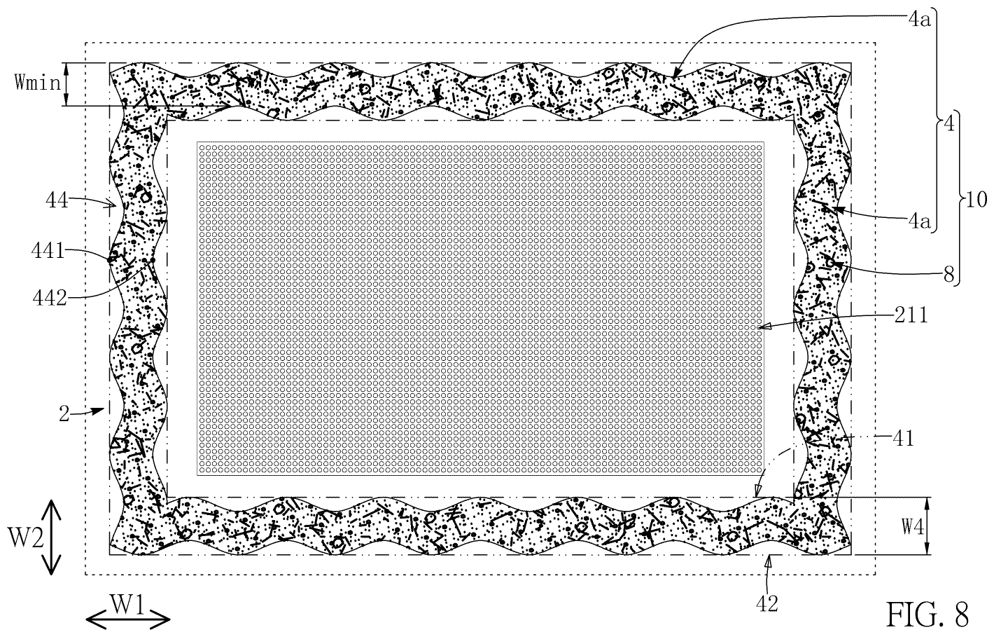

Moreover, when the adhesive layer 4 has the M number of the wave-shaped slots 44 (as shown in FIG. 1 to FIG. 4B, FIG. 8, and FIG. 9), the M number of the wave-shaped slots 44 are respectively recessed in the inner side 41 and the outer side 42 of the adhesive layer 4 and penetrate through the adhesive layer 4 along the predetermined direction D, and any two of the M number of the wave-shaped slots 44 located adjacent to each other and respectively arranged on the inner side 41 and the outer side 42 are only partially overlapped with each other along the width direction W1, W2. In other words, the M number of the wave-shaped slots 44 can be selectively provided and formed on the inner side 41 and the outer side 42 of the adhesive layer 4 in the above manner.

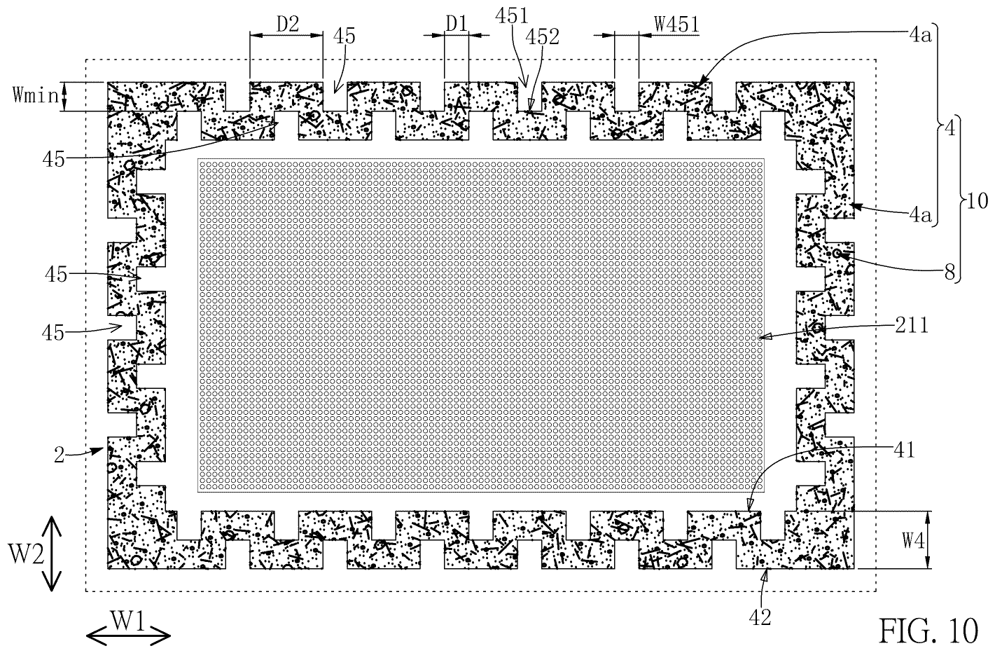

In addition, when the adhesive layer 4 has the N number of the rectangular slots 45 (as shown in FIG. 1 to FIG. 4B, FIG. 10, and FIG. 11), the N number of the rectangular slots 45 are respectively recessed in the inner side 41 and the outer side 42 of the adhesive layer 4 and penetrate through the adhesive layer 4 along the predetermined direction D, and any two of the N number of the rectangular slots 45 located adjacent to each other and respectively arranged on the inner side 41 and the outer side 42 are not overlapped with each other along the width direction W1, W2. In other words, the N number of the rectangular slots 45 can be selectively provided and formed on the inner side 41 and the outer side 42 of the adhesive layer 4 in the above manner.

It should be noted that the arrangement of the buffering cavities 43, the wave-shaped slots 44, and the rectangular slots 45 of the adhesive layer 4 in the present embodiment needs to meet the following conditions for preventing the adhesive layer 4 from having insufficient structural strength. In a cross-sectional view of the adhesive layer 4 perpendicular to the predetermined direction D, a minimum width Wmin of the adhesive layer 4 in the width direction W1, W2 is greater than or equal to 50% of the predetermined width W4. Specifically, a position of the minimum width Wmin corresponds to (or is labeled at) a portion of the adhesive layer 4 having a largest ratio of the buffering cavities 43, the wave-shaped slots 44, and/or the rectangular slots 45 along the width direction W1, W2.

The light-permeable layer 5 in the present embodiment is a transparent and flat glass board, but the present disclosure is not limited thereto. The light-permeable layer 5 has an outer surface 51 and an inner surface 52 that is opposite to the outer surface 51. The light-permeable layer 5 (e.g., the inner surface 52) is disposed on the adhesive layer 4, so that the inner surface 52 of the light-permeable layer 5, the ring-shaped support 10, and the electronic component 2 jointly define an enclosed space E. The inner side 41 of the adhesive layer 4, the exposed portion 832 of at least one of the exposed additives 83, and the optical region 211 of the electronic component 2 are arranged in the enclosed space E.

The encapsulant 6 of the present embodiment is opaque for blocking a visible light from passing therethrough. The encapsulant 6 is a liquid encapsulation and is formed on the upper surface 11 of the substrate 1, and edges of the encapsulant 6 are flush with edges of the substrate 1. The electronic component 2, the ring-shaped support 10, the light-permeable layer 5, and each of the metal wires 3 are embedded in the encapsulant 6 (e.g., the outer side 42 of the adhesive layer 4 is connected to the encapsulant 6), and the outer surface 51 of the light-permeable layer 5 is at least partially exposed from the encapsulant 6, but the present disclosure is not limited thereto.

In summary, when the optical device 100 of the present embodiment has a high temperature (or is heated), the adhesive layer 4 can be selectively formed with at least one type of the L number of the buffering cavities 43, the M number of the wave-shaped slots 44, and the N number of the rectangular slots 45, thereby effectively reducing a stress strength generated from the adhesive layer 4. Accordingly, problems relating to delamination of the adhesive layer 4 or damage of the component adhered to the adhesive layer 4 (e.g., the electronic component 2 or the light-permeable layer 5) can be improved.

### First Configuration

It should be noted that the above description describes the common features of possible configurations of the adhesive layer 4. For example, FIG. 1 to FIG. 4B show a first configuration of the adhesive layer 4 provided by the present embodiment, and when the adhesive layer 4 has the M number of the wave-shaped slots 44 and the N number of the rectangular slots 45, the M number of the wave-shaped slots 44 are formed on one of the segments 4a, and the N number of the rectangular slots 45 are formed on another one of the segments 4a. Moreover, when the adhesive layer 4 further has the L number of the buffering cavities 43, the L number of the buffering cavities 43 do not correspond along the width direction W1, W2 in position to any one of the M number of the wave-shaped slots 44 and any one of the N number of the rectangular slots 45.

Specifically, a quantity and an arrangement of any one type of the buffering cavities 43, the wave-shaped slots 44, and the rectangular slots 45 formed on the adhesive layer 4 can be adjusted or changed according to design requirements. Moreover, all possible configurations of the adhesive layer 4 cannot be shown in the drawings of the present embodiment, and the following description only describes some preferable configurations of the adhesive layer 4, but the present disclosure is not limited thereto. In addition, in the adhesive layer 4 described in the following description, L is greater than one, but the present disclosure is not limited thereto. For example, in other embodiments of the present disclosure not shown in the drawings, L can be equal to one.

### Second Configuration

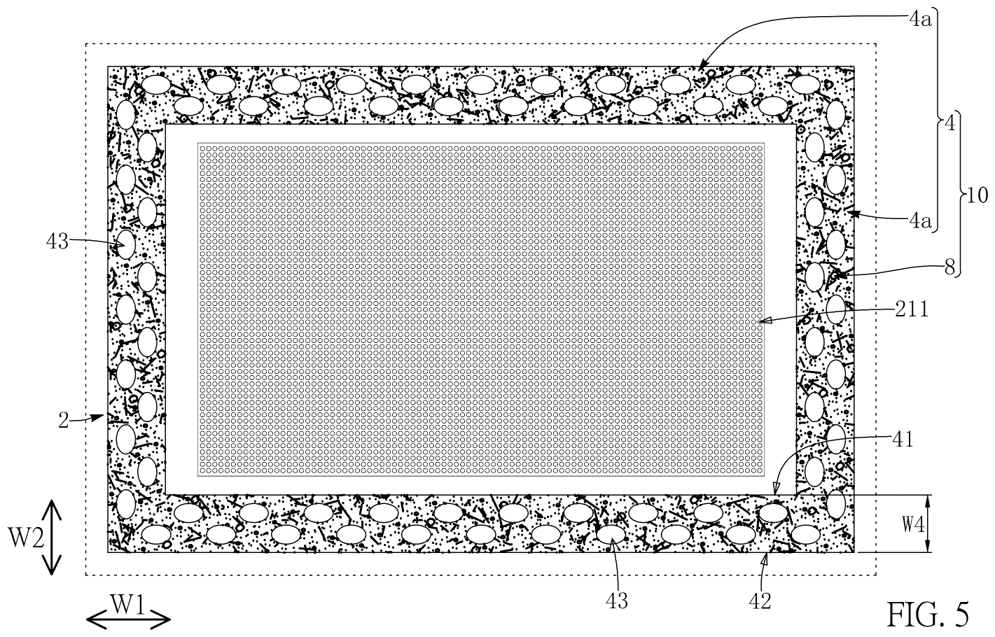

As shown in FIG. 5, the adhesive layer 4 (only) has the buffering cavities 43 respectively formed in the segments 4a. Any two of the buffering cavities 43 located adjacent to each other and arranged on a same one of the segments 4a are not overlapped with each other along the width direction W1, W2. Moreover, any one of the buffering cavities 43 is symmetrical to another one of the buffering cavities 43 relative to a center of the optical region 211, but the present disclosure is not limited thereto. For example, in other embodiments of the present disclosure not shown in the drawings, the buffering cavities 43 can be formed only in one of the segments 4a of the adhesive layer 4.

Furthermore, in the cross-sectional view of the adhesive layer 4, each of the buffering cavities 43 has an elongated shape (e.g., an ellipse), a total area of the buffering cavities 43 is less than or equal to 50% of an area jointly surrounded by the inner side 41 and the outer side 42 of the adhesive layer 4, thereby effectively preventing the structural strength of the adhesive layer 4 from being insufficient due to the buffering cavities 43.

### Third Configuration

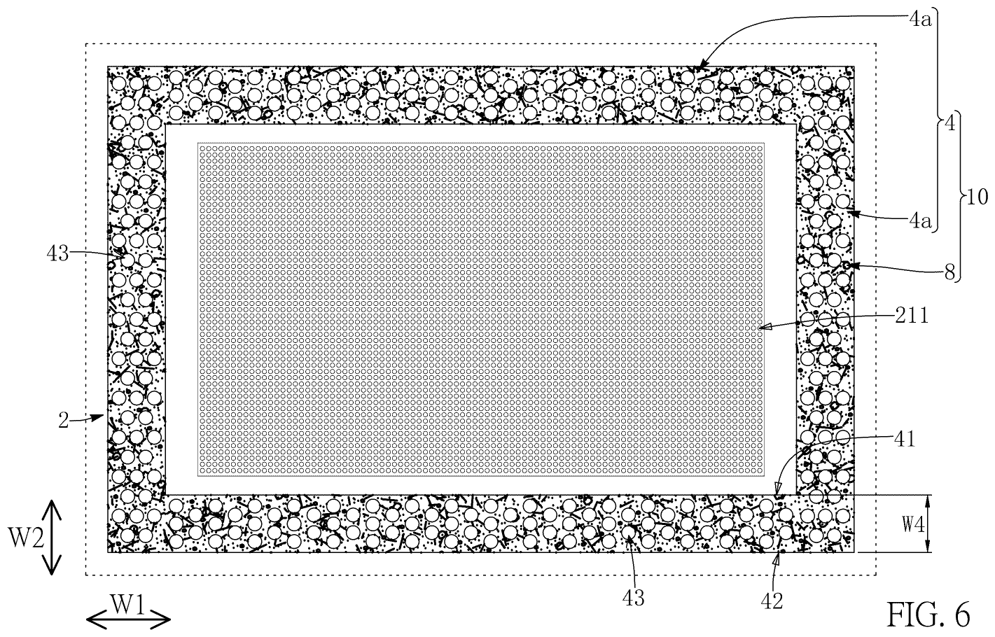

As shown in FIG. 6, the adhesive layer 4 (only) has the buffering cavities 43 respectively formed in the segments 4a. In any two of the buffering cavities 43 arranged on a same one of the segments 4a, one of the any two of the buffering cavities 43 is overlapped with another one of the any two of the buffering cavities 43 along the width direction W1, W2. Moreover, any one of the buffering cavities 43 is symmetrical to another one of the buffering cavities 43 relative to a center of the optical region 211, but the present disclosure is not limited thereto. For example, in other embodiments of the present disclosure not shown in the drawings, the buffering cavities 43 can be formed only in one of the segments 4a of the adhesive layer 4.

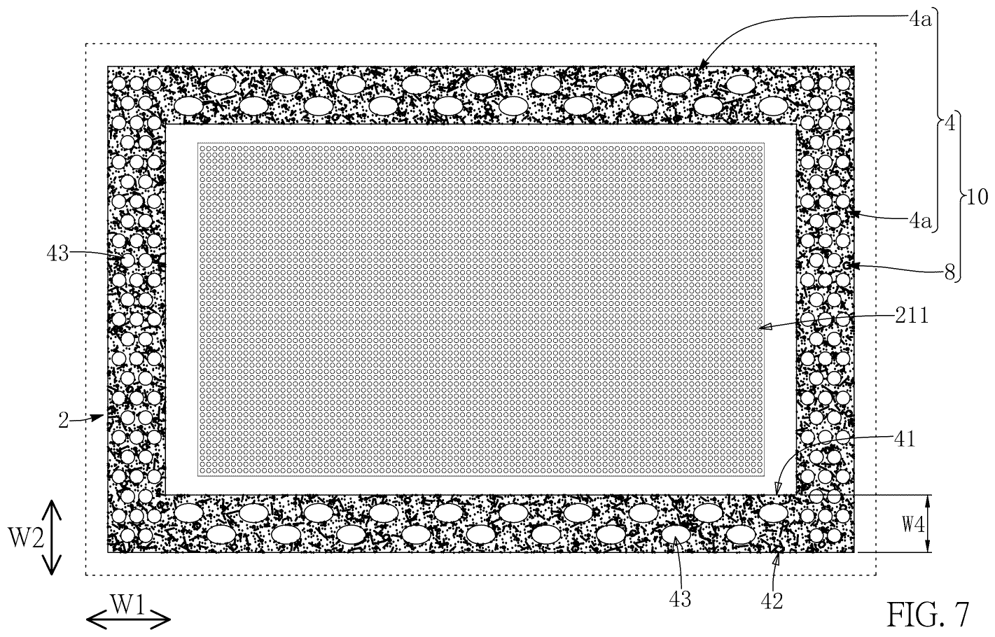

Furthermore, in the cross-sectional view of the adhesive layer 4, each of the buffering cavities 43 has a circular shape, a total area of the buffering cavities 43 is less than or equal to 50% of an area jointly surrounded by the inner side 41 and the outer side 42 of the adhesive layer 4, thereby effectively preventing the structural strength of the adhesive layer 4 from being insufficient due to the buffering cavities 43. Specifically, as shown in FIG. 7, the buffering cavities 43 can be formed of the elongated shape and the circular shape.

### Fourth Configuration

As shown in FIG. 8, the adhesive layer 4 (only) has the wave-shaped slots 44 respectively formed on the segments 4a. Any two of the wave-shaped slots 44 located adjacent to each other and respectively arranged on the inner side 41 and the outer side 42 are only partially overlapped with each other along the width direction W1, W2, but the present disclosure is not limited thereto. For example, in other embodiments of the present disclosure not shown in the drawings, the wave-shaped slots 44 can be formed only on one of the segments 4a of the adhesive layer 4.

Specifically, in any two of the wave-shaped slots 44 arranged on a same one of the segments 4a, located adjacent to each other, and respectively arranged on the inner side 41 and the outer side 42, a wave crest 441 of one of the two wave-shaped slots 44 corresponds along the width direction W1, W2 in position to a wave trough 442 of another one of the two wave-shaped slots 44, so that the wave crest 441 and the corresponding wave trough 442 can have the minimum width Wmin therebetween, thereby effectively preventing the adhesive layer 4 from having insufficient structural strength due to the wave-shaped slots 44.

### Fifth Configuration

As shown in FIG. 9, the adhesive layer 4 has the wave-shaped slots 44 and the buffering cavities 43, and the structures of the wave-shaped slots 44 and the buffering cavities 43 have been described in the above configurations. The following description only describes the arrangement of the wave-shaped slots 44 and the buffering cavities 43 for the sake of brevity. The wave-shaped slots 44 are respectively formed on two of the segments 4a, a part of (e.g., at least one of) the buffering cavities 43 is arranged between the wave-shaped slots 44, and the other buffering cavities 43 are arranged in another two of the segments 4a that are provided without the wave-shaped slots 44.

### Sixth Configuration

As shown in FIG. 10, the adhesive layer 4 (only) has the rectangular slots 45 respectively formed on the segments 4a. Any two of the rectangular slots 45 located adjacent to each other, formed on a same one of the segments 4a, and respectively arranged on the inner side 41 and the outer side 42 are not overlapped with each other along the width direction W1, W2, but the present disclosure is not limited thereto. For example, in other embodiments of the present disclosure not shown in the drawings, the rectangular slots 45 can be formed only on one of the segments 4a of the adhesive layer 4.

Specifically, any one of the rectangular slots 45 has a slot opening 451 arranged on the inner side 41 or the outer side 42 and a slot bottom 452 that is arranged away from the slot opening 451. Moreover, in any two of the rectangular slots 45 formed on a same one of the segments 4a and respectively arranged on the inner side 41 and the outer side 42, the slot bottoms 452 are preferably coplanar with each other, but the present disclosure is not limited thereto.

In other words, the slot opening 451 has a slot width W451. Any two of the rectangular slots 45 located adjacent to each other, arranged on a same one of the segments 4a, and respectively arranged on the inner side 41 and the outer side 42 have a distance D1 therebetween that is greater than or equal to the slot width W451. Moreover, any two of the rectangular slots 45 located adjacent to each other, arranged on a same one of the segments 4a, and being both arranged on the inner side 41 or the outer side 42 have a distance D2 therebetween that is at least three times of the slot width W451, but the present disclosure is not limited thereto.

### Seventh Configuration

As shown in FIG. 11, the adhesive layer 4 has the rectangular slots 45 and the buffering cavities 43, and the structures of the rectangular slots 45 and the buffering cavities 43 have been described in the above configurations. The following description only describes the arrangement of the rectangular slots 45 and the buffering cavities 43 for the sake of brevity. The rectangular slots 45 are respectively formed on two of the segments 4a, and the buffering cavities 43 are arranged in another two of the segments 4a that are provided without the rectangular slots 45.

In addition, it should be noted that the optical device 100 can be a first type of device being capable of receiving light L1, or a second type of device being capable of emitting light L2. For example, as shown in FIG. 12, the optical device 100 is a sensor package structure, the electronic component 2 is a sensor chip, and the ring-shaped support 10 is configured to weaken (or eliminate) the light L1 that passes through the light-permeable layer 5 and that travels thereon, thereby preventing the optical region 211 (e.g., a sensing region of the sensor chip) of the electronic component 2 from generating a flare phenomenon.

Moreover, as shown in FIG. 13, the optical device 100 can be a display mechanism, the electronic component 2 is a display, and the ring-shaped support 10 is configured to weaken the light L2 that is emitted from the optical region 211 of the electronic component 2 (e.g., a lighting region of the display) and that travels thereon, thereby preventing the light-permeable layer 5 from generating a light-spot.

### Beneficial Effects of the Embodiment

In conclusion, the adhesive layer of the optical device in the present disclosure is provided with the protruding microstructures through the additive module arranged therein, such that light traveling on to the inner side of the adhesive layer can be weakened through the protruding microstructures, thereby effectively preventing the light traveling on to the ring-shaped support from generating an abnormal refraction or reflection.

In addition, when the optical device provided by the present disclosure has a high temperature (or is heated), the adhesive layer can be selectively formed with at least two types of the L number of the buffering cavities, the M number of the wave-shaped slots, and the N number of the rectangular slots, thereby effectively reducing a stress strength generated from the adhesive layer. Accordingly, problems relating to delamination of the adhesive layer or damage of the component adhered to the adhesive layer (e.g., the electronic component or the light-permeable layer) can be improved.

Moreover, in the optical device provided by the present disclosure, the adhesive layer meets a specific structural condition (e.g., the minimum width is greater than or equal to 50% of the predetermined width), so that a quantity and an arrangement of any one type of the buffering cavities, the wave-shaped slots, and the rectangular slots formed on the adhesive layer can be adjusted or changed for meeting different design requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optical device, comprising:
an electronic component, wherein a top surface of the electronic component has an optical region and a carrying region that surrounds the optical region;
a ring-shaped support including:
an adhesive layer having a ring shape and being disposed on the carrying region of the electronic component, wherein the adhesive layer has an inner side and an outer side that is opposite to the inner side; and
an additive module being incompletely soluble in the adhesive layer and including:
a plurality of inner additives entirely embedded in the adhesive layer and arranged away from the inner side and the outer side of the adhesive layer; and
a plurality of shape-formation additives entirely embedded in the adhesive layer, wherein the shape-formation additives are arranged adjacent to the inner side of the adhesive layer, so as to enable the inner side of the adhesive layer to form a plurality of protruding microstructures; and
a light-permeable layer having an outer surface and an inner surface that is opposite to the outer surface, wherein the light-permeable layer is disposed on the ring-shaped support, and the inner surface of the light-permeable layer, the ring-shaped support, and the electronic component jointly define an enclosed space.

2. The optical device according to claim 1, wherein the additive module further includes a plurality of exposed additives each having an embedded portion and an exposed portion, wherein the embedded portion of each of the exposed additives is embedded in the adhesive layer, and the exposed portion of each of the exposed additives is exposed from the adhesive layer.

3. The optical device according to claim 2, wherein the additive module is made of a light-absorption material, and the inner additives, the shape-formation additives, and the exposed additives have at least two shapes that are different from each other.

4. The optical device according to claim 3, wherein the adhesive layer is light-permeable, and wherein, when light travels in the adhesive layer, the additive module absorbs at least part of the light.

5. The optical device according to claim 1, wherein the additive module is completely insoluble in the adhesive layer.

6. The optical device according to claim 1, wherein the optical device is a display mechanism, and the electronic component is a display.

7. The optical device according to claim 1, wherein the additive module further includes a plurality of dropped additives, and wherein the dropped additives are peeled from the adhesive layer, so as to enable the inner side of the adhesive layer to form a plurality of dimpled microstructures.

8. The optical device according to claim 1, wherein the optical device is a sensor package structure, and the electronic component is a sensor chip.

9. The optical device according to claim 8, further comprising:
a substrate, wherein the electronic component is disposed on the substrate along a predetermined direction and is electrically coupled to the substrate; and
an encapsulant formed on the substrate, wherein the electronic component, the adhesive layer, and the light-permeable layer are embedded in the encapsulant, and the outer surface of the light-permeable layer is at least partially exposed from the encapsulant.

10. The optical device according to claim 1, wherein the adhesive layer has at least two of an L number of buffering cavities, an M number of wave-shaped slots, and an N number of rectangular slots, in which L is a positive integer, and any one of M and N is a positive integer greater than one;
wherein, when the adhesive layer has the L number of the buffering cavities, each of the L number of the buffering cavities is arranged in the adhesive layer and penetrates through the adhesive layer along a predetermined direction;
wherein, when the adhesive layer has the M number of the wave-shaped slots, the M number of the wave-shaped slots are respectively recessed in the inner side and the outer side of the adhesive layer and penetrate through the adhesive layer along the predetermined direction, and any two of the M number of the wave-shaped slots located adjacent to each other and respectively arranged on the inner side and the outer side are only partially overlapped with each other along a width direction being perpendicular to the predetermined direction; and
wherein, when the adhesive layer has the N number of the rectangular slots, the N number of the rectangular slots are respectively recessed in the inner side and the outer side of the adhesive layer and penetrate through the adhesive layer along the predetermined direction, and any two of the N number of the rectangular slots located adjacent to each other and respectively arranged on the inner side and the outer side are not overlapped with each other along the width direction.
